(19) United States
(12) Patent Application Publication
(10) Pub. No.: US 2013/0023126 A1
(43) Pub. Date: Jan. 24, 2013

(54) Method for the manufacture of electronic devices with purified fluorine

(71) Applicants: Christoph Sommer, Neckarsulm (DE); Oliviero Diana, Vilvoorde (BE); Johannes Eicher, Sehnde (DE); Ercan Uenveren, Hannover (DE); Stefan Mross, Brussels (BE); Holger Pernice, Schwanewede (DE); Peter M. Predikant, Hannover (DE); Thomas Schwarze, Ahlten (DE); Reiner Fischer, Dettum (DE)

(72) Inventors: Christoph Sommer, Neckarsulm (DE); Oliviero Diana, Vilvoorde (BE); Johannes Eicher, Sehnde (DE); Ercan Uenveren, Hannover (DE); Stefan Mross, Brussels (BE); Holger Pernice, Schwanewede (DE); Peter M. Predikant, Hannover (DE); Thomas Schwarze, Ahlten (DE); Reiner Fischer, Dettum (DE)

(73) Assignee: SOLVAY SA, Brussels (BE)

(21) Appl. No.: 13/638,658

(22) PCT Filed: Apr. 7, 2011
(86) PCT No.: PCT/EP2011/055425

§ 371 Date: Oct. 1, 2012

(30) Foreign Application Priority Data
Apr. 8, 2010 (EP) 10159285.5

(51) Int. Cl. H01L 21/306

(52) U.S. Cl. 438/710; 257/E21.219

(57) ABSTRACT

Elemental fluorine is used as etching agent for the manufacture of electronic devices, especially semiconductor devices, micro-electromechanical devices, thin film transistors, flat panel displays and solar panels, and as chamber cleaning agent mainly for plasma-enhanced chemical vapor deposition (PECVD) apparatus. For this purpose, fluorine often is produced on-site. The invention provides a process for the manufacture of electronic devices wherein fluorine is produced on site and is purified from HF by a low temperature treatment. A pressure of between 1.5 and 20 Bars absolute is especially advantageous.

This application claims priority to European patent application no. 10159285.5 filed Apr. 8, 2010, the whole content of this application being incorporated herein by reference for all purposes.

The invention concerns a method for the manufacture of electronic devices with purified elemental fluorine.

Elemental fluorine (F₂) is often produced electrolytically from hydrogen fluoride (HF) in the presence of an electrolyte salt, usually in the presence of a molten HF adduct of KF having a formula of about KF·(1.8 to 2.3)HF at a voltage of at least 2.9 V (in practice, between 8 and 10 or 11 V) according to the equation (1):

2HF→H₂+F₂ (1)

F₂ is useful as etchant for the manufacture of electronic devices, especially semiconductors, photovoltaic cells, micro-electromechanical systems (“MEMS”), TFTs (thin film transistors for flat panel displays or liquid crystal displays), and the like, and as cleaning agent for treatment chambers used in the manufacture of electronic devices. For the manufacture of semiconductors, photovoltaic cells, MEMS and TFTs, several consecutive steps of deposition of layers and etching a part of them are performed in treatment chambers ; fluorine can be used for etching of layers constituted of very different constitution, for example, for etching silicon containing layers. Usually, during deposition processes performed in the treatment chambers—often CVD chambers (chambers wherein layers are deposited on items via chemical vapor deposition, e.g. plasma-enhanced CVD, metal organic CVD or low pressure CVD)—undesired deposits form on the walls and on inner constructive parts of the chamber and must be regularly removed. This is achieved by treating the deposits thermally or plasma-enhanced with elemental fluorine as chamber cleaning agent.

Fluorine is a very reactive molecule, and thus, for plants with a respectively great demand, elemental fluorine is preferably produced on-site. This means, that one or more fluorine generators are located on the site of the tools, and preferably, in proximity of the tools (CVD chambers, etching chambers) for manufacturing the electronic devices. It is especially preferred that the fluorine generator or generators be in fluid contact with one or more of the tools such that it is not necessary to fill the fluorine into a storage tank or into pressure bottles and transport it on or to the site of use.

Especially for the use of elemental fluorine as an etchant, but also when used as chamber cleaning agent, it is desirable that the elemental fluorine be very pure. Entrained solids and hydrogen fluoride (HF) are considered as especially undesired impurities.

WO 2006/043125 discloses a fluorine gas generator disposed in the gas feed system of a semiconductor plant. The pressure in the electrolytic cells is set to ambient pressure up to 820 torr and preferably, to ambient pressure up to 770 torr, and the pressure in a buffer tank is set, for example, to 0.18 MPa above atmospheric pressure (i.e. to about 2.8 Bara).

U.S. Pat. No. 5,589,148 discloses a method for purifying fluorine wherein impure fluorine is contacted with an alkaline earth metal hydroxide and an iron oxide.

U.S. Pat. No. 2,960,835 and WO 02/50334 (corresponding to US patent application publication 2002/0074013) disclose the removal of HF from F₂ by a low temperature treatment.

Object of the present invention is to provide an improved process for delivery of purified fluorine as agent to a process for the manufacture of electronic devices wherein it is desirable to use pure reagents. The invention concerns a method for the manufacture of electronic devices, especially semiconductors, photovoltaic cells, MEMS, or TFTs, comprising at least one step selected from the group consisting of etching of items in a chamber using elemental fluorine as etching agent, and cleaning a chamber using elemental fluorine as chamber cleaning agent, comprising at least a step of manufacture of the elemental fluorine by electrolysis wherein, after its manufacture and before its application as etching agent or chamber cleaning agent, the fluorine is subjected to a low temperature treatment at a pressure above ambient pressure to remove at least a part of entrained hydrogen fluoride.

The term “low temperature treatment” denotes a contact of the fluorine to be purified with cooled surfaces of a cooling apparatus, e.g. a cooled trap or a cooled heat exchanger wherein the cooled surfaces are cooled to a temperature of equal to or lower than −50° C. Preferably, they are cooled to a temperature of equal to or lower than −60° C. The temperature is preferably equal to or higher than −185° C. because, at ambient pressure, the boiling point of fluorine is about −188° C. Cooling liquids for this temperature range are generally known, e.g. from R. E. Rondeau, J. Chem. Eng. Data, II, 124 (1966). US patent application publication 2009-0026410 provides heat transfer fluids comprising an ether and an alkylbenzene which are suitable in heat exchangers operating at temperatures as low as −115° C. The melting point of HF under standard pressure (100 kPa) is −83.6° C. Thus, under the conditions of the process of the invention, and depending from the pressure, the HF in the trap will solidify if the temperature is respectively low ; the higher the pressure, the lower the temperature at which the HF solidifies.

The pressure of the fluorine during the low temperature treatment is preferably equal to or greater than 1.5 Bar absolute (150 kPa abs.); the term “Bar abs.” is equivalent to “Bara”. More preferably, the pressure is equal to or greater than 2 bar (abs). The pressure is preferably equal to or lower than 20 Bara (2.000 kPa abs.), and more preferably, it is equal to or lower than 15 Bara (1.500 kPa abs).

Performing the process at a pressure in the upper region, e.g. between 6 and 20 bar (abs.), at a given temperature improves the separation of the entrained HF because the partial pressure of HF is lower at a higher pressure, and thus the residual content of HF in the treated fluorine is lower. On the other hand, for practical reasons it may be preferred to perform the process at a lower pressure, e.g. in the range from 2 to 4 bar (abs.) because F₂ is a very aggressive compound.

While performing the process at a temperature as low as possible improves the separation factor (because the partial pressure of HF is lower), it is preferred to select pressure and temperature such that the separated HF does not solidify because the separated HF can be removed from the trap more easily in liquid state than HF being in a solid state. The removal of HF at conditions at which the condensed HF is liquid is preferred. As mentioned above, at ambient pressure, HF solidifies at about −83.6° C. Under the elevated pressure of the process of the invention, the solidification temperature is lower, thus, the process can be performed at temperatures even lower than −83.6° C. A preferred range for the treatment at low temperature is from equal to or greater than −70° C. to equal or higher than −82° C.

The fluorine can be manufactured, if desired, on site. This is a preferred embodiment of the invention. It can be produced in one or more satellite plants, e.g. in a fluorine generating cassette as described in WO 2004/009873. If desired, each cassette can be allocated to one or more process chambers wherein etching is performed ; or a plurality of fluorine generating cassettes is connected to a fluorine gas distribution system which is connected to the chambers. The means, e.g. a cooled trap, for performing the inventive method for the low temperature purification can be integrated into the cassette.

The process can also be performed in the frame of a plant according to the skid concept as described in unpublished U.S. provisional patent applications no. 61/383204, filed Sep. 15, 2010, and 61/383533, filed Sep. 16, 2010, both filed in the name of Solvay SA.

If produced on site, one embodiment provides for the manufacture of fluorine for the manufacture of photovoltaic devices, for example, photovoltaic cells. The manufacture of photovoltaic cells and etching agents and etching agent compositions comprising F₂ useful therein are described in WO 2009/092453 and EP-A 2159829. In this embodiment, the pressure of delivery of the fluorine to the tool is preferably equal to or higher 1.5 Bar abs. It is preferably equal to or lower than 5 Bara. A preferred range for the pressure in this embodiment is 1.5 to 4.5 Bara. The process of the invention can be performed at the same pressure. If desired, the process of the invention is performed at a higher pressure, preferably from 8 to 12 Bara, because, as explained above, the separation of HF is better at higher pressure. The fluorine is then depressurized to a pressure in the preferred range of 1.5 to 5 Bara.

In another embodiment of on site production with greater demand of fluorine, especially in the manufacture of TFTs for LCDs, the pressure of delivery of the fluorine to the tool is preferably equal to or greater than 3 Bara (300 kPa abs.), and especially preferably, equal to or greater than 4.5 Bara (450 kPa abs). In this embodiment, the pressure is preferably equal to or lower than 12 Bara (1.200 kPa abs), and more preferably, it is equal to or lower than 11 Bara (1.100 kPa abs). An especially preferred range in this embodiment is 4.5 to 11 Bara (450 to 1.100 kPa abs). In this embodiment, the process of the present invention and the delivery to the tool are preferably performed at a pressure in the range of 8 to 12 Bara (800 to 1200 hPa). The advantage is that no additional pressurization is needed. If the process of the invention is performed at a lower pressure than the step of the fluorine delivery to the tool, the fluorine must be pressurized in a compressor or other means. The manufacture of TFTs and etching agents comprising F₂ useful therein is described in unpublished EP patent application 09174034.0 filed on 26 Oct. 2009 (corresponding to unpublished international patent application no. PCT/EP2010/066109 filed on Oct. 26, 2010).

By means of the low temperature treatment, HF which usually is entrained in electrolytically produced F₂ can be removed effectively. If desired, a further treatment with an adsorbent or absorbent, e.g. NaF, can be performed after the low temperature treatment. The fluorine can be contacted with the adsorbent or absorbent under the same pressure as applied for removing HF from it at low temperature. Alternatively, the fluorine can be pressurized to a higher pressure or depressurized to a lower pressure for contacting it with the absorbent. Alternatively or additionally, a step of pressure distillation can be performed. Entrained solids which are mainly composed of solidified electrolyte salt can be removed in a frit made from F₂-resistant material, especially stainless steel, nickel or Monel metal.

According to one embodiment, the removal of solids from the electrolytically produced F₂ can be performed by passing the F₂ through a jet scrubber operated with liquid HF at a low temperature, e.g. with liquid HF at a temperature of −70° C. or lower, down to −82° C. Such a treatment is described in European patent application no. 10172034.0 filed Aug. 05, 2010 in the name of Solvay SA.

In such a combination of low temperature treatment and absorption, the advantage is that less absorbent must be regenerated. The removed HF can be recycled to the electrolysis reactor.

The “chamber” is a chamber wherein electronic devices are etched thermally or assisted by a remote and/or internal plasma, or it is a chamber used for deposition of layers, e.g. by chemical vapor deposition (CVD), especially a plasma-enhanced CVD chamber (PECVD) which is to be cleaned from time to time or according to a schedule to remove undesired deposits which accumulate on the walls and internal parts.

The process of the present invention and the delivery of the purified fluorine can be performed on the site of use or on a site apart from its point of use. If it is performed apart from the site of use, the fluorine will be stored in a storage tank for transport purposes. If the fluorine is produced on site, it may be stored in a storage tank; the storage tank can also be applied as buffer tank. If the fluorine generator is sufficiently close to the fluorine applying tool, the fluorine must not be collected in a storage tank.

The step or steps of purification can be performed before or after storage or buffering (if a step of storage or buffering is foreseen). If desired, the fluorine can be purified before and after storage.

After its manufacture and purification, the fluorine is delivered to the point of use. This is preferably performed under a pressure which is greater than ambient pressure.

In a preferred embodiment, the fluorine is pressurized by means of compressors. If acceptable for the intended purpose, pressurizing inert gases can be applied, for example, nitrogen, oxygen, helium or argon. Preferably, no pressurizing gas is applied, except for elemental fluorine as pressurizing gas.

The step of storage, if foreseen, preferably denotes the storage of the elemental fluorine in suitable tanks, e.g. stainless steel bottles.

The fluorine is preferably generated on site of its point of use via electrolysis in an apparatus which is in fluid communication with the process chamber or process chambers. This means that the generated elemental fluorine is not filled into a storage tank or into pressurized bottles, which are then disconnected from the delivery line. If desired, the fluorine is stored in storage tanks, buffer tanks or bottles only which remain connected to the delivery line. Often, the fluorine generator is located on the same plant as the tools wherein it is used, i.e. in a distance of less than 500 m from the manufacturing tools ; the generator often will be located near the tools, e.g. in a distance of 100 m or less from the tools. They can even be located in close proximity to the process chamber as the point of use, e.g. the distance can be 10 m or less.

The step of delivery preferably denotes passing the fluorine from the manufacturing apparatus to the point of use through pipes, especially through pipes which remain permanently connected to prevent intrusion of air into the fluorine, and to prevent fluorine to leak out.

In a preferred embodiment, the step of low temperature treatment to remove HF, the step of delivery of the treated F₂ to the point of use, any step of storage and the optional, but preferably performed steps of removing entrained solids and removal of any residual HF by means of an adsorption or absorption, preferably by contacting the F₂ with NaF, are performed at a pressure greater than ambient pressure; preferably, the steps are performed at a pressure equal to or greater than 1.5 bar (abs), and more preferably, at a pressure equal to or greater than 2 bar (abs). Preferably, said steps are performed at a pressure equal to or lower than 20 bar (abs).

According to one embodiment, said steps are performed at a pressure in the lower range, especially in the range of 1.5 to 4.5 Bara (150 to 450 hPa) if photovoltaic devices, for example, photovoltaic cells, are to be produced.

In another embodiment of on site production with greater demand of fluorine, especially in the manufacture of TFTs for LCDs, the pressure of the fluorine in said steps to the tool is preferably equal to or greater than 3 Bara.

The method of the present invention allows for the delivery of elemental fluorine to the point of use with a low content of HF, or with no HF at all.

Should the disclosure of any patents, patent applications, and publications which are incorporated herein by reference conflict with the description of the present application to the extent that it may render a term unclear, the present description shall take precedence.

The following example is intended to explain the invention in detail without limiting it.

### EXAMPLE 1

### Provision of Elemental Fluorine With Low HF Content On-Site to the Point of Use For Chamber Cleaning

### 1. Manufacture of Elemental Fluorine

An electrolyte salt with a composition of about KF.2HF is filled into an electrolysis cell, heated to about 80-120° C. and molten therein. HF is introduced into the electrolytic cell. A voltage of between 8 to 10 V is applied, and current is passed through the composition of the molten electrolyte salt and hydrogen fluoride ; the content of the cell is kept in a range of about 80 to 100° C. Elemental fluorine and elemental hydrogen form in the respective electrode compartments. The generated elemental fluorine is passed through a Monel metal frit to remove solids and pressurized by means of a compressor to about 10 Bar abs. and then passed through a trap cooled to −80° C.; in this trap, entrained HF condenses. The gaseous F₂ leaving the trap is passed through a bed of NaF to remove any residual HF.

### 2. Delivery of the Purified F₂ to the Chamber

The compressed fluorine is then passed, if desired after depressurization to about 2 to 3 Bar abs., in a pipe directly to a semiconductor-manufacturing tool located on-site. In this tool, the elemental fluorine is applied for the cleaning of the inner walls of a plasma chamber to remove silicon-containing residues deposited during the PECVD (plasma-enhanced vapor deposition) layers in a process for the manufacture of semiconductors.

### EXAMPLE 2

### Provision of Elemental Fluorine with Low HF Content On-Site to the Point of Use For Etching

### 1. Manufacture of Elemental Fluorine

The manufacture of the elemental fluorine including the low temperature treatment is performed as described in example 1.1.

### 2. Delivery of the Purified F₂ to the Tool

The compressed fluorine obtained in example 2.1 is then passed under a pressure of 2 to 3 Bar abs. through a pipe directly to a semiconductor-manufacturing tool located on-site. In this tool, the elemental fluorine is applied in admixture with N₂ and Ar in a volume ratio of Ar:N₂:F₂ of 10:70:20 for the etching of SiₓN_{y} layers (x is about 3 and v is about 4) on a Si wafer in a plasma chamber in a process for the manufacture of semiconductors.

### EXAMPLE 3

### Provision of F₂ With Very Low HF Content for TFT Manufacture

### 1. Manufacture of Elemental Fluorine

An electrolyte salt with a composition of about KF.2HF is filled into an electrolysis cell, heated to about 80-120° C. and molten therein. HF is introduced into the electrolytic cell. A voltage of between 8 to 10 V is applied, and current is passed through the composition of the molten electrolyte salt and hydrogen fluoride. Elemental fluorine and elemental hydrogen form in the respective electrode compartments.

### 2. Delivery of the Purified F₂ to the Tool

The generated elemental fluorine is passed through a Monel metal frit to remove solids and pressurized by means of a compressor to about 10 Bar abs. and then passed through a trap cooled to −100° C.; in this trap, entrained HF condenses.

The gaseous F₂ leaving the trap is passed through a bed of NaF to remove any residual HF and then delivered, under a pressure of about 10 Bara, to a tool for the manufacture of thin film transistors for liquid crystal displays (TFT-LCD).

### EXAMPLE 4

### Provision of F₂ with Very Low HF Content For Photovoltaic Cell Manufacture

### 1. Manufacture of Elemental Fluorine

An electrolyte salt with a composition of about KF.2HF is filled into an electrolysis cell, heated to about 80-120° C. and molten therein. HF is introduced into the electrolytic cell. A voltage of between 8 to 10 V is applied, and current is passed through the composition of the molten electrolyte salt and hydrogen fluoride. Elemental fluorine and elemental hydrogen form in the respective electrode compartments.

### 2. Delivery of the purified F₂ to the tool

The generated elemental fluorine is passed through a Monel metal frit to remove solids and pressurized by means of a compressor to about 4 Bar abs. and then passed through a trap cooled to −100° C.; in this trap, entrained HF condenses.

The gaseous F₂ leaving the trap is passed through a bed of NaF to remove any residual HF and then delivered, under a pressure of about 4 Bara, to a tool for the manufacture of photovoltaic cells.

### EXAMPLE 5

### Provision of F₂ with Very Low HF Content For Photovoltaic Cell Manufacture

### 1. Manufacture of Elemental Fluorine

An electrolyte salt with a composition of about KF.2HF is filled into an electrolysis cell, heated to about 80-120° C. and molten therein. HF is introduced into the electrolytic cell. A voltage of between 8 to 10 V is applied, and current is passed through the composition of the molten electrolyte salt and hydrogen fluoride. Elemental fluorine and elemental hydrogen form in the respective electrode compartments.

### 2. Delivery of the Purified F₂ to the Tool

The generated elemental fluorine is passed through a Monel metal frit to remove solids and pressurized by means of a compressor to about 4 bar (abs.) and then passed through a trap cooled to −80° C., by means of a heat exchanger through which a cooling liquid is passed ; in this trap, entrained HF condenses.

The gaseous F₂ leaving the trap is passed at the pressure of 4 bar (abs) through a bed of NaF to remove any residual HF, passed again through a Monel metal frit to remove any solids still contained, and is then delivered, under a pressure of about 4 Bara, to a tool for the manufacture of photovoltaic cells.

1. A method for the manufacture of electronic devices comprising
at least a step for the manufacture of elemental fluorine on site electrolytically; and
at least one step selected from the group of etching of items in a chamber using elemental fluorine as etching agent and cleaning a chamber using elemental fluorine as chamber cleaning agent,
wherein the elemental fluorine after its manufacture and before its application for etching or chamber cleaning is subjected to a low temperature treatment at a pressure above ambient pressure to remove at least a part of entrained hydrogen fluoride.

2. The method of claim 1, wherein the pressure during the low temperature treatment is equal to or greater than 1.5 Bars absolute.

3. The method of claim 1, wherein the pressure during the low temperature treatment is equal to or lower than 20 Bars absolute.

4. The method of claim 1, wherein the electronic devices are selected from the group consisting of semiconductors, photovoltaic cells, micro-electromechanical systems (MEMS), and thin film transistors (TFTs).

5. The method of claim 4, being for the manufacture of photovoltaic cells, wherein the pressure is in the range of 1.5 to 4.5 Bars absolute.

6. The method of claim 4, being for the manufacture of thin film transistors (TFTs), wherein the pressure is in the range of 4.5 to 11 Bars absolute.

7. The method of claim 1, wherein the elemental fluorine is cooled in the low temperature treatment to a temperature equal to or lower than −50° C.

8. The method of claim 7, wherein the elemental fluorine is cooled in the low temperature treatment to a temperature equal to or lower than −60° C.

9. The method of claim 1, wherein the elemental fluorine is additionally subjected to a further step selected from the group consisting of at least one adsorption step, at least one absorption step, and at least one distillation step.

10. The method of claim 1, wherein the elemental fluorine is produced by electrolysis of HF in the presence of a molten HF adduct of KF as electrolyte salt.

11. The method of claim 1, wherein elemental fluorine is produced in a generator in the manufacturing step, and wherein the generator for elemental fluorine is in fluid communication with the chamber.

12. The method of claim 1, wherein the etching chamber or the chamber to be cleaned is a thermal or plasma-assisted chamber.

13. The method of claim 1, comprising the cleaning step, wherein the cleaning step is performed thermally or plasma-assisted.

14. The method of claim 1, wherein the elemental fluorine is manufactured in a cassette.

15. The method of claim 1, wherein the elemental fluorine is manufactured in a skid.

16. The method of claim 1, wherein HF is removed at a temperature from −70° C. to −82° C.

17. The method of claim 1, wherein solids are removed from the F₂ by passing the F₂ through a jet scrubber operated with liquid HF.

18. The method of claim 17, wherein solids are removed at a pressure greater than ambient pressure.
